(19) United States
(12) Patent Application Publication
(10) Pub. No.: US 2011/0083711 A1
(43) Pub. Date: Apr. 14, 2011

(54) ENERGY GENERATING DEVICE COMPRISING A PHOTOVOLTAIC CONVERTER AND A THERMOELECTRIC CONVERTER, THE LATTER CONVERTER BEING INCLUDED WITHIN THE SUPPORTING SUBSTRATE OF THE PHOTOVOLTAIC CONVERTER

(75) Inventors: Marc Plissonnier, Eybens (FR); Stephanie Capdeville, Toulouse (FR); Frederic Gaillard, Voiron (FR); Jean-Philippe Mulet, Ozoir-La-Ferriere (FR); Sebastien Noel, Rives (FR); Jean Philippe Schweitzer, Seine Port (FR); Jerome Gilles, L'Hay Les Roses (FR)

(73) Assignees: Comm. A L'Energie Atom. et aux Energies Alterna, Paris (FR); SAINT-GOBAIN GLASS FRANCE, Courbevoie (FR)

(21) Appl. No.: 12/808,494

(22) PCT Filed: Dec. 17, 2008
(86) PCT No.: PCT/EP2008/067748

§ 371 Date: Dec. 21, 2010

(30) Foreign Application Priority Data
Dec. 17, 2007 (FR) 07 59890

(51) Int. Cl. H01L 35/02; H01L 21/30

(52) U.S. Cl. 136/206; 438/54; 257/E21.211

(57) ABSTRACT

An elementary device to generate electric energy including a photovoltaic converter and a thermoelectric converter. The photovoltaic converter includes a stack of layers, resting on a supporting substrate in heat-insulating material, including a first conductive layer as an upper electrode, and a second conductive layer as a lower electrode, the upper and lower electrodes sandwiching a layer in photoactive material between them. The thermoelectric converter includes a third conductive layer acting as a hot junction and a fourth conductive layer acting as a cold junction, the hot and cold junctions sandwiching between them an element in thermoelectric and electrically conductive material. The thermoelectric and electrically conductive element is included in the thickness of the supporting substrate, so that one end is in contact with the hot junction and the other end is in contact with the cold junction.

### TECHNICAL FIELD

The invention pertains to the area of energy recovery and conversion systems. In particular, it concerns a device capable of coupling a photovoltaic converter with a thermo-electric converter to produce electric energy.

### STATE OF THE PRIOR ART

Photovoltaic converters, also called solar cells, are used to convert light energy into electric energy. They essentially consist of a supporting substrate, formed in electrically insulating and heat insulating material, on which there lies a stack of layers consisting of a n/p junction comprising two semiconductor layers (one n-type layer and the other p-type) and of two electrically conductive layers located either side of the n/p junction, one of the faces of the n/p junction intended to be subjected to light radiation.

The problem with photovoltaic converters is that their output power decreases significantly with rises in temperature. For example, for photovoltaic converters in crystalline silicon, the loss of output power is in the region of 0.4 to 0.5% for every added degree Celsius (see document [1] referenced at the end of this description).

One solution used to attenuate this power reduction consists of coupling the photovoltaic converter with a thermoelectric converter. A thermoelectric converter effectively allows heat to be converted to electric energy, by using the difference in temperature existing between two ends of a thermoelectric material.

In the prior art, two types of coupling between a photovoltaic converter and a thermoelectric converter are known.

First, according to document [2] referenced at the end of this description, a thermoelectric converter and a photovoltaic converter can be coupled by placing the thermoelectric converter 2 underneath the photovoltaic converter 1, the photovoltaic converter being oriented so that it faces light radiation.

As illustrated in FIG. 1, a device is thereby obtained comprising a supporting substrate 3 on one face of which there lies a photovoltaic converter 2 comprising a stack of one layer of n-doped semiconductor material 12 and one layer of p-doped semiconductor material 13 (forming a n/p junction 14) sandwiched between an electrically conductive layer (upper electrode 10) and another electrically conductive layer (lower electrode 11) and, on the opposite face, a thermoelectric converter 2 comprising a layer of thermoelectric material 24 sandwiched between an electrically conductive layer 20 and another electrically conductive layer 21 (in FIG. 1 the thermoelectric effect is symbolized by the symbol ΔT).

The problem with this particular configuration is that it does not allow use of the maximal thermal gradient produced in the photovoltaic converter, namely the thermal gradient generated by the supporting substrate of the photovoltaic converter due to its thermally insulating properties.

Additionally, the thermal coupling between the photovoltaic converter and the thermoelectric converter, via the supporting substrate, is relatively poor on account of the thermally insulating properties of the supporting substrate. Therefore the hot-cold temperature difference in the thermoelectric converter is accordingly lower and little productive in terms of electric energy production.

The other type of known coupling is described in document [3], referenced at the end of this description. Two electrodes formed in thermoelectric and electrically conductive materials are arranged one on the face of the photovoltaic converter facing light radiation, and the other buried underneath the photovoltaic converter.

This type of coupling is schematized in FIG. 2. On a supporting substrate 3, a stack of layers is placed comprising a layer of n-type semiconductor material 120 and a layer of p-type semiconductor material 130 (forming a n/p junction 140), the stack being sandwiched between a layer of electrically conductive and thermoelectric material (forming both the upper electrode 30 of the photovoltaic converter and the hot junction 30 of the thermoelectric converter) and a layer of electrically conductive and thermoelectric material (forming both the lower electrode 31 of the photovoltaic converter and the cold junction 31 of the thermoelectric converter).

With this type of coupling, advantage is drawn from the difference in temperature existing through the thickness of the n/p junction of the photovoltaic converter, namely between the front face of the photovoltaic converter and its buried part. A difference in temperature may arise when the n/p junction of the photovoltaic converter is subjected to light radiation e.g. sun rays.

By depositing thermoelectric materials on the opposite faces of the photovoltaic converter (front face and buried face in contact with the supporting substrate of the photovoltaic converter), it becomes possible to make use of this temperature difference via thermoelectric conversion.

In general, with the knowledge that the electric power recovered by a thermoelectric converter is higher the greater the difference in temperature, it is ascertained that this second configuration is only of advantage if the thermal resistance of the materials forming the n/p junction of the photovoltaic converter is high. As a result, it is inferred that this type of coupling is limited to photovoltaic converters made in materials with low thermal conductivity, such as a photovoltaic material of GaN type, so that light rays are able to heat the upper part of the photovoltaic converter and the lower part remains “cold”.

This type of coupling cannot be envisaged therefore with photovoltaic converters made in silicon, in which thermal resistance is very low, since the difference in temperature and hence the electric energy recovered by thermoelectric effect would be negligible. Yet photovoltaic converters in silicon are the most common photovoltaic converters.

Also, in the particular case of thin layer photovoltaic converters, this type of coupling does not function at all since the thermal gradient of the photovoltaic converter remains zero.

Bearing in mind that the thermal power generated by light absorption i.e. 80% of light power is not used by a photovoltaic converter alone, and that known solutions to overcome this problem are not satisfactory, the inventors have set themselves the objective of recovering part of this thermal energy by coupling a photovoltaic converter with a thermoelectric converter in an original manner.

### DISCLOSURE OF THE INVENTION

This objective is achieved with an elementary device to generate electric energy comprising a photovoltaic converter and a thermoelectric converter,

the photovoltaic converter comprising a stack of layers lying on a supporting substrate in heat insulating material, the stack of layers comprising a first electrically conductive layer acting as upper electrode, and a second electrically conductive layer acting as lower electrode, the upper and lower electrodes sandwiching a layer of photoactive material between them,

the thermoelectric converter comprising a third electrically conductive layer acting as hot junction, a fourth electrically conductive layer acting as cold junction, the hot and cold junctions sandwiching an element in thermoelectric and electrically conductive material between them,

characterized in that the thermoelectric and electrically conductive element is included in the thickness of the supporting substrate in heat insulating material of the photovoltaic converter, so that one end of said element is in contact with the hot junction and the other end of said element is in contact with the cold junction.

Here, according to the invention, a photovoltaic converter is coupled with a thermoelectric converter in such manner that it is possible to make use of the thermal gradient generated by the supporting substrate in electrically insulating material, generally glass, of the photovoltaic converter.

Advantageously, the first electrically conductive layer is transparent to incident rays.

Advantageously the hot junction and the lower electrode are one and the same electrically conductive layer.

Advantageously, the thermoelectric and electrically conductive element is included in the entirety of the thickness of the supporting substrate.

According to one embodiment, the supporting substrate is a substrate in glass i.e. in silica.

According to another embodiment, the supporting substrate is a substrate in aerogel. Advantageously, the supporting substrate is a substrate in silica aerogel.

It is recalled that an aerogel is a material similar to a gel in which the liquid component is replaced by a gas. An aerogel is a solid of very low density which has high heat insulation properties (thermal conductivity of less than 0.2 W.m⁻¹.K⁻¹).

Advantageously, the layer of photoactive material of the photovoltaic converter comprises a layer of first semiconductor material of n-type and a layer of second semiconductor material of p-type.

The thermoelectric and electrically conductive element can be in metal or semiconductor material.

Advantageously, the thermoelectric and electrically conductive element comprises a first thermoelectric and electrically conductive material of n-type, and a second thermoelectric and electrically conductive material of p-type.

Advantageously, the thermoelectric and electrically conductive element comprises a first thermoelectric and semiconductor material of n-type, and a second thermoelectric and semiconductor material of p-type.

The invention also concerns a system to generate electric energy. This system comprises i photovoltaic converters and i thermoelectric converters, i being an integer of 2 or more, said i photovoltaic converters and said i thermoelectric converters respectively being electrically connected in series,

each photovoltaic converter comprising a stack of layers lying on a supporting substrate in heat insulating material, the stack of layers comprising a first electrically conductive layer acting as upper electrode, and a second electrically conductive layer acting as lower electrode, the upper and lower electrodes sandwiching a layer of photoactive material between them,

each thermoelectric converter comprising a third electrically conductive layer acting as hot junction, a fourth electrically conductive layer acting as cold junction, the hot and cold junctions sandwiching between them an element in thermoelectric and electrically conductive material of n-type and an element in thermoelectric and electrically conductive material of p-type, the elements of n-type and p-type being spaced apart,

characterized in that the n-type element and the p-type element of each thermoelectric converter is included in the thickness of the supporting substrate of each photovoltaic converter in heat-insulating material, so that one end of the n-type element and one end of the p-type element are in contact with one same hot junction and so that the other end of the n-type element and the other end of the p-type element are in contact with cold junctions belonging to adjacent thermoelectric converters.

Advantageously, the supporting substrates of the photovoltaic converters are one and the same supporting substrate for all the photovoltaic converters.

Advantageously, each hot junction and each lower electrode are one and the same electrically conductive layer.

Advantageously, the thermoelectric materials of n-type and p-type are semiconductor materials of n-type and p-type.

According to one embodiment, the supporting substrates are substrates in glass i.e. in silica.

According to another embodiment, the supporting substrates are substrates in aerogel. Advantageously, the supporting substrates are substrates in silica aerogel.

The invention concerns a method to fabricate an elementary energy generating device such as described above. This method comprises the following steps:

a) providing a supporting substrate in heat-insulating and electrically-insulating material,

b) depositing an electrically conductive layer on one of the faces of the supporting substrate,

c) etching a hole in the thickness of the supporting substrate starting from the face opposite the face comprising the electrically conductive layer deposited at step b), as far as said electrically conductive layer,

d) filling said hole with a thermoelectric and electrically conductive compound and sintering said compound,

e) depositing an electrically conductive layer on the face of the supporting substrate opposite the face comprising the electrically conductive layer deposited at step b),

f) depositing a layer of photoactive material on one of the electrically conductive layers,

g) depositing an electrically conductive layer on the layer of photoactive material,

the electrically conductive layer deposited at step g) forming the upper electrode of the photovoltaic converter,

the electrically conductive layer on which the layer of photoactive material is deposited at step f) forming both the lower electrode of the photovoltaic converter and the hot junction of the thermoelectric converter,

the remaining, electrically conductive layer forming the cold junction of the thermoelectric converter.

It is specified that the sintering of the thermoelectric and electrically conductive compound is conducted at a temperature and pressure which depend on the material chosen, this temperature and this pressure being able to be easily determined by the person skilled in the art.

According to one embodiment, step f) is conducted after step b) and before step c).

According to another embodiment, steps f) and g) are performed after step b) and before step c).

Advantageously, after step b) and before step f), the method further comprises a step m) to deposit an electrically conductive layer on an already deposited electrically conductive layer, step f) being replaced by a step f′) to deposit a layer of photoactive material on the face of the supporting substrate comprising two electrically conductive layers,

the electrically conductive layer deposited at step g) forming the upper electrode of the photovoltaic converter,

the electrically conductive layer deposited at step m) forming the lower electrode of the photovoltaic converter,

the electrically conductive layer present between the supporting substrate and the electrically conductive layer deposited at step m) forming the hot junction of the thermoelectric converter,

the remaining, electrically conductive layer forming the cold junction of the thermoelectric converter.

Advantageously, the electrically conductive layer forming the upper electrode is in material transparent to light rays.

According to one particular embodiment, the method further comprises a step h) to structure the electrically conductive layer deposited at step g) to obtain an openwork electrically conductive layer. This structuring may consist of etching intended to impart a grid shape to the electrically conductive layer.

Advantageously, the supporting substrate is a substrate in glass or aerogel, preferably in silica aerogel.

The invention also concerns a method to obtain an energy generating system such as described above. This method comprises the following steps:

a) providing a supporting substrate in heat-insulating and electrically insulating material,

b) depositing an electrically conductive layer on the front face of the supporting substrate,

c) structuring the electrically conductive layer deposited at step b) to form i conductive traces electrically insulated from each other, i being an integer of 2 or more,

d) etching 2i holes in the thickness of the supporting substrate starting from the back face of said supporting substrate as far as the conductive traces of the front face of the support substrate, so as to obtain a pair of two holes per conductive trace,

e) forming 2i elements in thermoelectric and electrically conductive materials at the 2i holes, one of the elements of each pair of two holes being in a thermoelectric compound of n-type and the other element of each pair of two holes being in a thermoelectric compound of p-type,

f) depositing an electrically conductive layer on the back face of the supporting substrate,

g) structuring the electrically conductive layer deposited at step f) to form j conductive traces electrically insulated from each other, with j=i+1, the i conductive traces of the front face and the j conductive traces of the back face being arranged so as to connect the n-type and p-type elements in series, each element of one type being connected to two elements of the other type via a trace i and via a trace j respectively,

h) depositing a layer in photoactive material on one of the faces of the supporting substrate comprising a structured electrically conductive layer,

i) structuring this layer in photoactive material to form blocks connecting two adjacent conductive traces obtained at step g),

j) depositing an electrically conductive layer on the face of the supporting substrate comprising the layer of photoactive material,

k) structuring the electrically conductive layer deposited at step j) to form electrically conductive traces insulated from each other and connecting two adjacent blocks,

the electrically conductive layer structured at step k) forming the upper electrode of each photovoltaic converter,

the structured electrically conductive layer located between the layer of structured photoactive material and the supporting substrate forming both the lower electrode of each photovoltaic converter and the hot junction of each thermoelectric converter,

the remaining, structured electrically conductive layer forming the cold junction of each thermoelectric converter.

According to one embodiment, steps h) and i) are conducted after step c) and before step d).

According to another embodiment, steps h), i), j) and k) are conducted after step c) and before step d).

According to one variant, after step b) and before step c), the method further comprises a step b′) to deposit an electrically conductive layer on the electrically conductive layer deposited at step b), step c) becoming a step c′) to structure the electrically conductive layers deposited at steps b) and b′) to form i conductive traces electrically insulated from each other, i being an integer of 2 or more, and step h) becoming step h′) to deposit a layer in photoactive material on the front face of the supporting substrate,

the electrically conductive layer structured at step k) forming the upper electrode of each photovoltaic converter,

the electrically conductive layer deposited at step b′) and structured at step c′) forming the lower electrode of each photovoltaic converter,

the electrically conductive layer deposited at step b) and structured at step c′) forming the hot junction of each thermoelectric converter,

the remaining, structured electrically conductive layer forming the cold junction of each thermoelectric converter.

According to another variant, after step f) and before step g), the method further comprises a step f′) to deposit an electrically conductive layer on the electrically conductive layer deposited at step f), step g) becoming a step g′) to structure the electrically conductive layers deposited at steps f) and f′) to form j conductive traces electrically insulated from each other, with j=i+1, the i conductive traces of the front face and the j conductive traces of the back face being arranged so as to connect the n-type and p-type elements in series, each element of one type being connected to two elements of the other type via a trace i and via a trace j respectively,

the electrically conductive layer structured at step k) forming the upper electrode of each photovoltaic converter,

the electrically conductive layer deposited at step f′) and structured at step g′) forming the lower electrode of each photovoltaic converter,

the electrically conductive layer deposited at step f) and structured at step g′) forming the hot junction of each thermoelectric converter,

the remaining, structured electrically conductive layer forming the cold junction of each thermoelectric converter.

Advantageously, step e) to form the 2i elements comprises the following steps:
filling the 2i holes, one of the holes of each pair of two holes being filled with a n-type thermoelectric compound and the other hole of each pair of two holes being filled with a p-type thermoelectric compound,
sintering the compounds.

Advantageously, the thermoelectric materials are in powder form or paste form obtained by mixing powders with a binder.

Advantageously, at step h), the layer of photoactive material comprises a layer of n-type semiconductor material and a layer of p-type semiconductor material.

Finally, the invention concerns firstly the use of the thermoelectric converter of the elementary energy generating device such as described above to cool the photovoltaic converter of said elementary device, and secondly the use of the thermoelectric converters of the energy generating system such as described above to cool the photovoltaic converters of said system.

### BRIEF DESCRIPTION OF THE DRAWINGS

The invention will be better understood and other advantages and aspects will become apparent on reading the following description given as a non-limiting example accompanied by the appended drawings in which:

FIG. 1, already described above, illustrates one type of coupling between a photovoltaic converter and a thermoelectric converter according to the prior art,

FIG. 2, already described above, illustrates another type of coupling between a photovoltaic converter and a thermoelectric converter known from the prior art,

FIG. 3 illustrates the elementary energy generating device according to the invention,

FIG. 4 illustrates the energy generating system according to the invention,

FIG. 5 is an equivalent electric layout for the system illustrated in FIG. 4,

FIGS. 6A to 6D illustrate the steps of the method to obtain the elementary energy generating device according to the invention,

FIGS. 7A to 7F illustrate the steps of the method to obtain the energy generating system according to the invention.

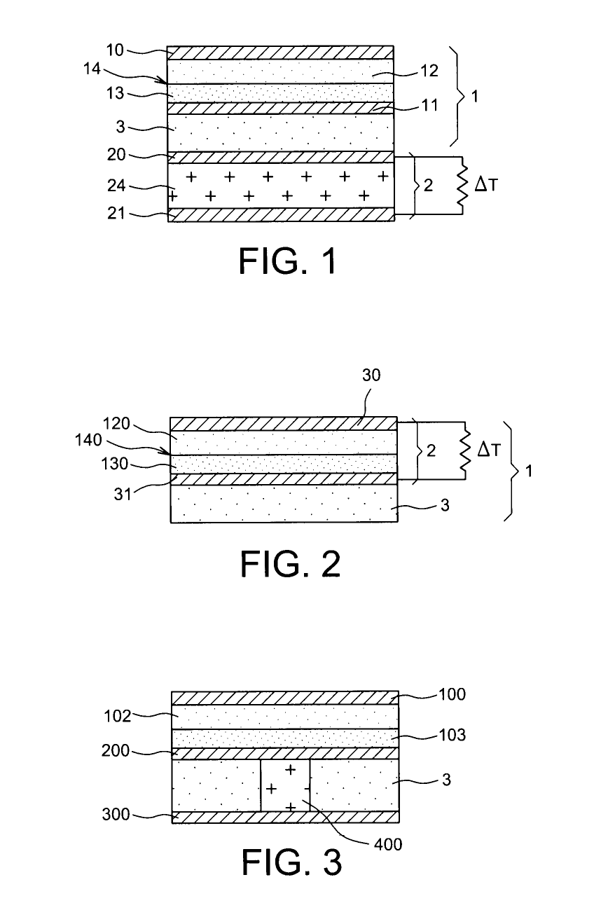

### DETAILED DESCRIPTION OF PARTICULAR EMBODIMENTS

A description will now be given of an elementary device to generate energy according to the invention, as illustrated by the example in FIG. 3.

According to a first embodiment, an electrically conductive layer is deposited on the upper face of a supporting substrate 3 in electrically insulating and heat-insulating material. It is possible for example to deposit a layer of molybdenum on a glass substrate (FIG. 6A). In this embodiment, one same electrically conductive layer will act both as lower electrode 200 of the photovoltaic converter and as hot junction 200 of the thermoelectric converter. However, it is possible to choose to deposit two electrically conductive layers, one on the other, one thereof acting as lower electrode of the photovoltaic converter and the other acting as hot junction for the thermoelectric converter.

Next, a through hole is made in the thickness of the supporting substrate 3 starting from the lower face of the supporting substrate as far as the electrically conductive layer present on its upper face, for example by chemical etching (lithographic etching) (FIG. 6B).

The hole is then filled with a thermoelectric and electrically conductive material.

It is preferable to use a material in powder form or paste form obtained by mixing powder(s) and a binder to achieve suitable filling of the hole. The material in powder or paste form is then sintered to obtain good cohesion of the thermoelectric material in the hole and also to ensure good ohmic contact between the thermoelectric material and the electrically conductive layer. This gives a thermoelectric element 400 which, here, is in the form of a bar (according to the shape of the hole) (FIG. 6C).

For example, sintering can be conducted at a temperature of 410° C. and at a pressure of 2 tonnes/cm².

The back face of the support substrate is then metalized. In this manner, what will become the cold junction 300 of the thermoelectric converter can be formed (FIG. 6C).

Next, on the upper face of the supporting substrate 3, i.e. on the layer of molybdenum, a layer of p-type semiconductor material 103 is deposited, followed by the depositing of a layer of n-type semiconductor material 102 to obtain a n/p junction. The materials under consideration may respectively be p-doped silicon and n-doped silicon.

Finally, an electrically conductive layer is deposited on this n/p junction, for example a Ni—Cu metal layer, to form the upper electrode 100 of the photovoltaic converter (FIG. 6D). This metal layer is etched to form a grid so that the underlying layer is able to receive light rays. To improve the collection of charge carriers, the etched metal layer can be associated with a transparent, electrically conductive layer (e.g. in TCO) deposited directly on the junction.

According to another embodiment, it is possible to form two through holes in the thickness of the supporting substrate. In this case, the two holes are respectively filled with a n-type thermoelectric material and a p-type thermoelectric material; it is possible for example to fill one of the holes with a p-type semiconductor material and the other hole with a n-type semiconductor material in powder form, and the material is then sintered. This gives a n-type bar and a p-type bar.

It is then continued as explained above by depositing an electrically conductive layer on the back face of the supporting substrate as per a pattern designed so that the end of the p-type semiconductor bar and the end of the n-type semiconductor bar are not in electric contact via this metallization layer. Metallization can be obtained, for example, by serigraphy or by photolithography of an electrically conductive layer.

The other non-described steps are identical to those described for the first embodiment.

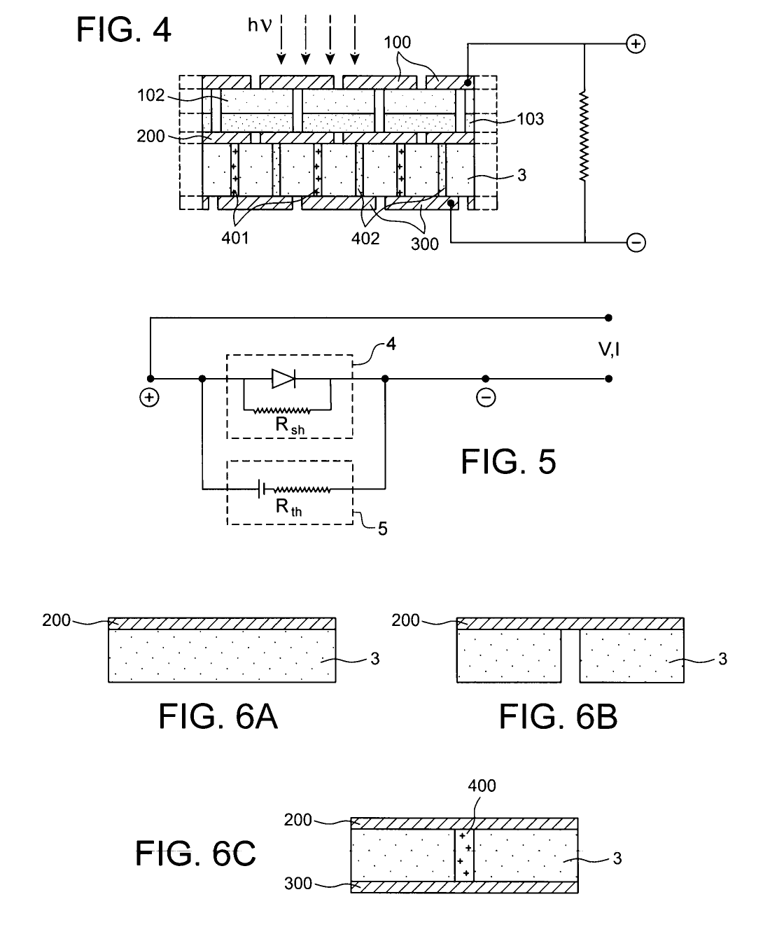

The forming of an energy generating system will now be described which comprises several photovoltaic converters and several thermoelectric converters connected in series, as illustrated for example in FIG. 4. The equivalent electric layout for said energy generating system is given in FIG. 5.

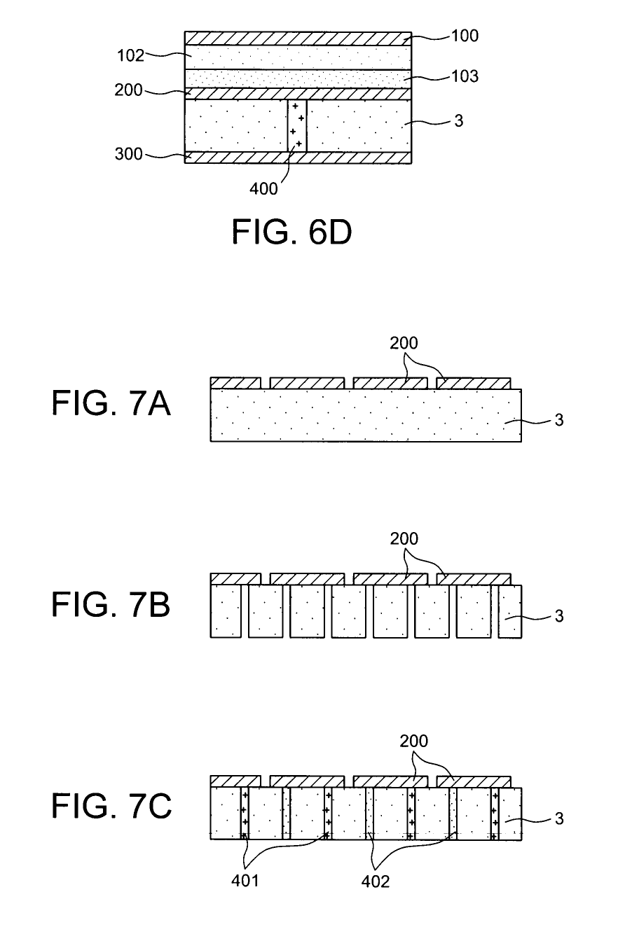

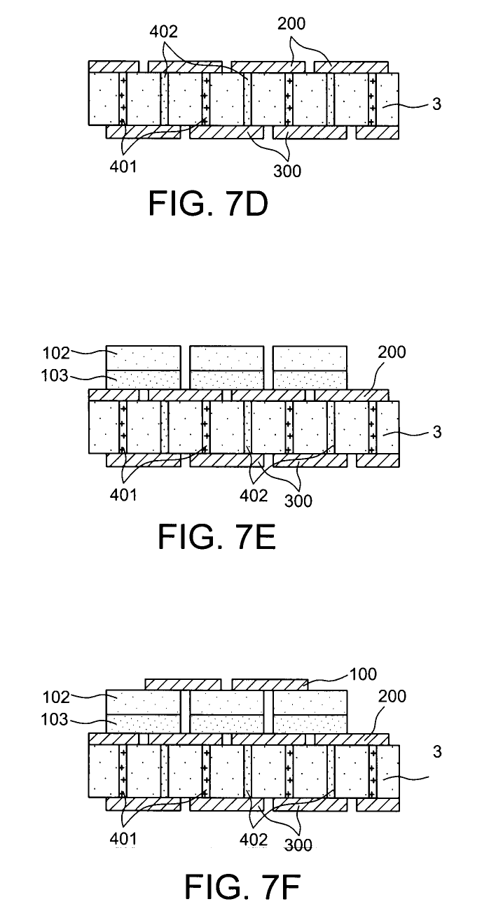

On the front face of a supporting substrate 3 in electrically and thermally insulating material, for example a substrate in glass, an electrically conductive layer is deposited and is etched with a pattern so as to obtain electrically conductive traces (in this manner the lower electrodes 200 of the photovoltaic converters and the hot junctions 200 of the thermoelectric converters are formed) (FIG. 7A). The electrically conductive layer may be a layer in molybdenum for example.

Next, the back face of the glass substrate 3 is etched to obtain pairs of two holes, each pair of two holes opening onto a conductive trace located on the front face of the supporting substrate (FIG. 7B).

The holes are then filled with a powder or paste of thermoelectric and electrically conductive materials of n- and p-type, for example semiconductor materials, to obtain a bar in n-type material 401 and a bar in p-type material 402 after sintering for each conductive trace. With sintering it is possible to obtain cohesion of the materials inside the holes and to ensure good ohmic contact between the bars and their respective conductive traces (FIG. 7D).

The back face of the support substrate is then metallised as per a pattern intended to form an electric connection between adjacent bars but belonging to different pairs, one of p-type and the other of n-type (FIG. 7D). In this manner thermoelectric converters connected in series are obtained.

To fabricate the photovoltaic converters of the device, a layer of first semiconductor material 103 is deposited on the front face of the supporting substrate, and a layer of second semiconductor material 102. It may be a semiconductor material of n-type and a semiconductor material of p-type, or vice versa, for example a layer of n-doped silicon and a layer of p-doped silicon. These two layers are then etched over their entire thickness in a pattern e.g. strips to connect two adjacent conductive traces (FIG. 7E). It is specified that in the illustrated examples, the photovoltaic converters always have a n/p junction (i.e. two layers, one n-type semiconductor layer and one of p-type), but evidently the n/p junction can be replaced by a single layer of photoactive material.

Finally, an electrically conductive layer is deposited on the front face of the supporting substrate, and it is structured by etching for example so that it at least partly covers two adjacent n/p junctions, so as to form an electric connection between adjacent n/p junctions (FIG. 7F).

In the system thus formed, use is made of the interconnections in series of the photovoltaic converters and of the electric insulation of their lower electrode via the supporting substrate to achieve a connection in series of the thermoelectric converters. Contrary to known prior art devices, the lower electrode of the photovoltaic converters serves to connect the photovoltaic converters electrically in series, but also serves as hot junction for the thermoelectric converters, in this case the lower electrode acts as connection between the n and p bars of one same thermoelectric converter.

In the particular case of an energy generating system according to the invention comprising several photovoltaic converters and several thermoelectric converters, it is of particular importance to pay heed to a particular configuration for the placing of the layers and their patterned etching to avoid any electric short circuit inside said energy generating system.

In both embodiments presented above, the device and system obtained result from the integration of one or more thermoelectric converters in the thickness of a supporting substrate used to support one or more photovoltaic converters, the lower electrode of the photovoltaic converters acting as hot junction for the thermoelectric converters. According to the invention, advantage is drawn from the heat-insulating nature of the supporting substrate for the one or more photovoltaic converters, generally in glass, and the supporting substrate is functionalized which, in addition to acting as support for the one or photovoltaic converters, is also used to generate a thermal gradient which can be used by the one or more thermoelectric converters.

According to one particular embodiment, the supporting substrate may be a layer of aerogel in material with low thermal conductivity (less than 0.2 W.m⁻¹.T⁻¹), for example a silica aerogel. The use of an aerogel allows a layer to be obtained in which it is easier to etch holes. In this case, to reinforce the supporting role of the supporting substrate in aerogel, it is optionally possible to provide an additional, more rigid support than the aerogel layer, for example a glass substrate underneath the metallization layer acting as cold junction for the thermoelectric converter(s). This additional support can be placed in position at the end of the method to fabricate the device, underneath the metallization layer acting as cold junction. It can also be placed in position at the start of the fabrication method, provided the order of the steps of the above-described method is reversed i.e. forming the cold junction on the support, depositing the supporting substrate in aerogel thereupon and forming holes in the thickness thereof, forming n- and p-type bars in the holes, forming the hot junctions, forming the n/p junctions and the upper electrodes of the photovoltaic converters.

In all cases, according to the invention, irrespective of the rigidity of the chosen supporting substrate, it is important to choose a material having very low thermal conductivity and which is electrically insulating, bearing in mind that the greater the heat insulation of the material, the more it is possible to optimize the performance level of the thermoelectric converter part of the device. It is hence possible to adapt the operating yield of the heat generated by the photovoltaic converter(s) of the device, in relation to the material chosen to form the supporting substrate.

The advantage of the elementary device and system according to the invention is that it is possible to optimize their power. Since simultaneous use is made of the photovoltaic current and of the thermoelectric current, it is necessary to achieve optimization of the internal resistances of the photovoltaic converter(s) and thermoelectric converter(s) to obtain maximum electric power from the two energy sources and an optimal conversion yield.

As schematized in FIG. 5, the functioning of a photovoltaic converter 4 can be likened to the functioning of a diode and a resistance in series (Rₛ) and in parallel (Rₛₕ), whilst the functioning of a thermoelectric converter 5 can be likened to a resistance Rₜₕ in which Rₜₕ=Rₜₕ(n)+Rₜₕ(p), Rₜₕ(n) being the resistance of the p-type bar and Rₜₕ(p) being the resistance of the n-type bar.

In FIG. 5, it is ascertained that to prevent the current from flowing in the thermoelectric converter 5, the following condition is required:

$$\frac{{R}_{sh}}{{R}_{th}} \leq 1.$$

Therefore the optimal arrangement of the system according to the invention is obtained when:

$$\frac{{R}_{sh}}{{R}_{th}} \leq 1$$

It is known that the value of resistance Rₛₕ depends on the characteristics of the junction of the photovoltaic converter, i.e. of the constituent materials of this n/p junction. If the n and p materials are obtained from doped silicon, the value of resistance Rₛₕ cannot be modulated if it is desired to obtain an optimal conversion yield.

It is known that the value of resistance Rₜₕ on the other hand depends on the electric properties of the constituent materials of the thermoelectric converter. It is therefore possible to modulate the value of Rₜₕ by modifying the composition of the thermoelectric materials. It is also possible to modify the value of Rₜₕ by choosing a particular geometry adapted to form the hot junction of the thermoelectric converter connecting the bars n and p, in order to meet the necessary condition for the proper functioning of the device.

Another advantage of the system according to the invention is that the thermoelectric converter(s) of the system can also function in Peltier mode i.e. they can use an electric current to produce a drop in temperature thereby allowing cooling of the photovoltaic converter and hence reduce the lowered performance of the photovoltaic converter caused by heat. Use of this cooling can also be made in the elementary energy generating device according to the invention.

A description will now be given of an example of embodiment of a photovoltaic module of chalcopyrite type.

The lower electrode is in molybdenum and is coated with a functional layer consisting of an absorbing agent in chalcopyrite.

The absorbing agent in chalcopyrite can preferably consist of ternary chalcopyrite compounds which generally contain copper, indium and selenium. It is also possible to add gallium to the layer of absorbing agent (e.g. Cu(In,Ga)Se₂ or CuGaSe₂), or aluminium (e.g. Cu(In,Al)Se₂), or sulphur (e.g. CuIn(Se,S). All these compounds are generally designated below under the term: layers of chalcopyrite absorbing agent.

The functional layer of chalcopyrite absorbing agent is coated with a thin layer of cadmium sulphide (CdS) making it possible to create a n/p junction with the chalcopyrite layer. Since the chalcopyrite absorbing agent is generally n-doped and the CdS layer is p-doped, this makes it possible to create the n/p junction required for setting up an electric current.

This thin CdS layer is itself coated with a bonding layer generally formed of so-called intrinsic zinc oxide (ZnO:i).

To form the upper electrode, the layer of ZnO:i is coated with a conductive layer in TCO (Transparent Conductive Oxide). It may be chosen from among the following materials: doped tin oxide, notably with fluorine or antimony (the precursors which can be used for CVD depositing may be organometallics or tin halides associated with a fluorine precursor of hydrofluoric acid or trifluoroacetic acid type), doped zinc oxide, notably with aluminium (the precursors which can be used for CVD depositing may be organometallics or halides of zinc and aluminium), or doped indium oxide, notably with tin (the precursors which can be used for CVD depositing may be organometallics or tin and indium halides). This conductive layer must be as transparent as possible and have high light transmission over all the wavelengths corresponding to the absorption spectrum of the material forming the functional layer, so as to avoid unnecessarily reducing the yield of the solar module.

The stack of thin layers is trapped between two substrates via an interlayer in PU, PVB or EVA for example. The first substrate differs from the second substrate through the fact that it is necessarily in alkaline-based glass (for reasons explained in the preamble to the invention), such as silico-sodo-calcic glass, so as to conform a solar or photovoltaic cell. The assembly is then peripherally encapsulated by means of a seal or sealing resin. One example of the composition of this resin and its conditions of use is described in document [4] referenced at the end of this description.

### BIBLIOGRAPHY

[1] M. Najarian and E. Garnett, “Thermoelectrics and Photovoltaics: Integration Challenges and Benefits”, MSE 226, Dec. 13, 2006.
[2] US 2006/0225782.
U.S. Pat. No. 4,710,588 (A).
EP 739042.

1-33. (canceled)

34. An elementary device to generate electric energy comprising:
a photovoltaic converter; and
a thermoelectric converter;
the photovoltaic converter comprising a stack of layers resting on a supporting substrate in heat-insulating material, the stack of layers comprising a first electrically conductive layer acting as an upper electrode, and a second electrically conductive layer acting as a lower electrode, the upper and lower electrodes sandwiching a layer of photoactive material between them,
the thermoelectric converter comprising a third electrically conductive layer acting as a hot junction and a fourth electrically conductive layer acting as a cold junction, the hot and cold junctions sandwiching an element in thermoelectric and electrically conductive material between them,
wherein the thermoelectric and electrically conductive element is included in the thickness of the supporting substrate in the heat-insulating material of the photovoltaic converter, so that one end of the conductive element is in contact with the hot junction and the other end of the conductive element is in contact with the cold junction, and the hot junction and the lower electrode are one and the same electrically conductive layer.

35. An elementary device generating electric energy according to claim 34, wherein the first electrically conductive layer is transparent to incident rays.

36. An elementary device generating electric energy according to claim 34, wherein the thermoelectric and electrically conductive element is included in the entirety of the thickness of the supporting substrate.

37. An elementary device generating electric energy according to claim 34, wherein the supporting substrate is a substrate in glass.

38. An elementary device generating electric energy according to claim 34, wherein the supporting substrate is a substrate in aerogel.

39. An elementary device generating electric energy according to claim 38, wherein the supporting substrate is a substrate in silica aerogel.

40. An elementary device generating electric energy according to claim 34, wherein the layer of photoactive material comprises a layer of first semiconductor material of n-type and a layer of second semiconductor material of p-type.

41. An elementary device generating electric energy according to claim 34, wherein the thermoelectric and electrically conductive element comprises a first thermoelectric and electrically conductive material of n-type, and a second thermoelectric and electrically conductive material of p-type.

42. An elementary device generating electric energy according to claim 34, wherein the thermoelectric and electrically conductive element comprises a first thermoelectric and semiconductor material of n-type, and a second thermoelectric and semiconductor material of p-type.

43. A system to generate electric energy comprising:
i photovoltaic converters and i thermoelectric converters, i being an integer of 2 or more, the i photovoltaic converters and the i thermoelectric converters respectively being electrically connected in series;
each photovoltaic converter comprising a stack of layers resting on a supporting substrate in heat-insulating material, the stack of layers comprising a first electrically conductive layer acting as an upper electrode, and a second electrically conductive layer acting as a lower electrode, the upper and lower electrodes sandwiching a layer of photoactive material between them;
each thermoelectric converter comprising a third electrically conductive layer acting as a hot junction and a fourth electrically conductive layer acting as a cold junction, the hot and cold junctions sandwiching between them an element in thermoelectric and electrically conductive material of n-type and an element in thermoelectric and electrically conductive material of p-type, the elements of n-type and p-type being spaced apart;
wherein the n-type element and the p-type element of each thermoelectric converter is included in the thickness of the supporting substrate of each photovoltaic converter in the heat-insulating material, so that one end of the n-type element and one end of the p-type element are in contact with one same hot junction, and so that the other end of the n-type element and the other end of the p-type element are in contact with cold junctions belonging to adjacent thermoelectric converters.

44. A system to generate electric energy according to claim 43, wherein the supporting substrates of the photovoltaic converters are one and the same supporting substrate for all the photovoltaic converters.

45. A system to generate electric energy according to claim 43, wherein each hot junction and each lower electrode are one and the same electrically conductive layer.

46. A system to generate electric energy according to claim 43, wherein the thermoelectric materials of n-type and p-type are semiconductor materials of n-type and p-type.

47. A system to generate electric energy according to claim 43, wherein the supporting substrates are substrates in glass.

48. A system to generate electric energy according to claim 43, wherein the supporting substrates are substrates in aerogel.

49. A system to generate electric energy according to claim 48, wherein the supporting substrates are substrates in silica aerogel.

50. A method to fabricate an elementary device generating electric energy according to claim 34, comprising:
a) providing a supporting substrate in heat-insulating and electrically insulating material;
b) depositing an electrically conductive layer on one of faces of the supporting substrate;
c) etching a hole in the thickness of the supporting substrate starting from the face opposite the face comprising the electrically conductive layer deposited at the depositing b), as far as the electrically conductive layer;
d) filling the hole with a thermoelectric and electrically conductive compound and sintering the compound;
e) depositing an electrically conductive layer on the face of the supporting substrate opposite the face comprising the electrically conductive layer deposited at the depositing b);
f) depositing a layer of photoactive material on one of the electrically conductive layers;
g) depositing an electrically conductive layer on the layer of photoactive material;
the electrically conductive layer deposited at the depositing g) forming the upper electrode of the photovoltaic converter;
the electrically conductive layer on which the layer of photoactive material is deposited at the depositing f) forming both the lower electrode of the photovoltaic converter and the hot junction of the thermoelectric converter;
the remaining electrically conductive layer forming the cold junction of the thermoelectric converter.

51. A method to fabricate an elementary energy generating device according to claim 50, wherein the depositing f) is conducted after the depositing b) and before the etching c).

52. A method to fabricate an elementary energy generating device according to claim 50, wherein the depositings f) and g) are conducted after the depositing b) and before the etching c).

53. A method to fabricate an elementary energy generating system according to claim 50, further comprising, after the depositing b) and before the depositing f), m) depositing an electrically conductive layer on an already deposited electrically conductive layer, the depositing f) being replaced by a depositing f′) to deposit a layer of photoactive material on the face of the supporting substrate comprising two electrically conductive layers,
the electrically conductive layer deposited at the depositing g) forming the upper electrode of the photovoltaic converter,
the electrically conductive layer deposited at the depositing m) forming the lower electrode of the photovoltaic converter,
the electrically conductive layer present between the supporting substrate and the electrically conductive layer deposited at the depositing m) forming the hot junction of the thermoelectric converter,
the remaining electrically conductive layer forming the cold junction of the thermoelectric converter.

54. A method to fabricate an elementary energy generating device according to claim 50, wherein the electrically conductive layer forming the upper electrode is in material transparent to light rays.

55. A method to fabricate an elementary energy generating device according to claim 50, further comprising a structuring h) to structure the electrically conductive layer deposited at the depositing g) to obtain an openwork electrically conductive layer.

56. A method to fabricate an elementary energy generating device according to claim 50, wherein the supporting substrate is a substrate in glass, or aerogel, or a silica aerogel.

57. A method to obtain an energy generating system according to claim 43, comprising:
a) providing a supporting substrate in heat-insulating and electrically insulating material;
b) depositing an electrically conductive layer on the front face of the supporting substrate;
c) structuring the electrically conductive layer deposited at the depositing b) to form i conductive traces electrically insulated from each other, i being an integer of 2 or more;
d) etching 2i holes in the thickness of the supporting substrate starting from the back face of the supporting substrate as far as the conductive traces of the front face of the supporting substrate, so as to obtain a pair of two holes per conductive trace;
e) forming 2i elements in thermoelectric and electrically conductive materials at the 2i holes, one of the elements of each pair of two holes being in a thermoelectric compound of n-type, and the other element of each pair of two holes being in a thermoelectric compound of p-type;
f) depositing an electrically conductive layer on the back face of the supporting substrate;
g) structuring the electrically conductive layer deposited at the depositing f) to form j conductive traces insulated from each other, with j=i+1, the i conductive traces of the front face and the j conductive traces of the back face being arranged so as to connect the n-type elements and p-type elements in series, each element of one type being connected to two elements of the other type by a trace i and trace j respectively;
h) depositing a layer of photoactive material on one of the faces of the supporting substrate comprising a structured electrically conductive layer;
i) structuring this layer in photoactive material to form blocks connecting two adjacent conductive traces obtained at the structuring g);
j) depositing an electrically conductive layer on the face of the supporting substrate comprising the layer in photoactive material;
k) structuring the electrically conductive layer deposited at the depositing j) to form conductive traces electrically insulated from each other and connecting two adjacent blocks;
the electrically conductive layer structured at the structuring k) forming the upper electrode of each photovoltaic converter;
the structured electrically conductive layer located between the structured layer of photoactive material and the supporting substrate forming both the lower electrode of each photovoltaic converter and the hot junction of each thermoelectric converter;
the remaining, structured electrically conductive layer forming the cold junction of each thermoelectric converter.

58. A method to obtain an energy generating system according to claim 57, wherein the depositing h) and the structuring i) are conducted after the structuring c) and before the etching d).

59. A method to obtain an energy generating system according to claim 57, wherein the depositing h), the structuring i), the depositing j), and the structuring k) are conducted after the structuring c) and before the etching d).

60. A method to obtain an energy generating system according to claim 57, further comprising, after the depositing b) and before the structuring c), a depositing b′) to deposit an electrically conductive layer on the electrically conductive layer deposited at b), the structuring c) being replaced by a structuring c′) to structure the electrically conductive layer deposited at the depositing b) and b′) to form i conductive traces electrically insulated from each other, i being an integer of 2 or more, and the depositing h) being replaced by a depositing h′) to deposit a layer in photoactive material on the front face of the supporting substrate,
the electrically conductive layer structured at the structuring k) forming the upper electrode of each photovoltaic converter,
the electrically conductive layer deposited at the depositing b′) and structured at the structuring c′) forming the lower electrode of each photovoltaic converter,
the electrically conductive layer deposited at the depositing b) and structured at the structuring c′) forming the hot junction of each thermoelectric converter,
the remaining, structured electrically conductive layer forming the cold junction of each thermoelectric converter.

61. A method to obtain an energy generating system according to claim 57, further comprising, after the depositing f) and before the structuring g), a depositing f′) to deposit an electrically conductive layer on the electrically conductive layer deposited at the depositing f), the structuring g) being replaced by a structuring g′) to structure the electrically conductive layers deposited at the depositing f) and f′) to form j conductive traces electrically insulated from each other, with j=i+1, the i conductive traces of the front face and the j conductive traces of the back face being arranged so as to connect the n-type elements and p-type elements in series, each element of one type being connected to two elements of the other type by a trace i and by a trace j respectively,
the electrically conductive layer structured at the structuring k) forming the upper electrode of each photovoltaic converter,
the electrically conductive layer deposited at the depositing f′) and structured at the structuring g′) forming the lower electrode of each photovoltaic converter,
the electrically conductive layer deposited at the depositing f) and structured at the structuring g′) forming the hot junction of each thermoelectric converter,
the remaining, structured electrically conductive layer forming the cold junction of each thermoelectric converter.

62. A method to obtain an energy generating system according to claim 24, wherein the forming e) to form the 2i elements comprises:
filling the 2i holes, one of the holes of each pair of two holes being filled with a thermoelectric compound of n-type, and the other hole of each pair of two holes being filled with a thermoelectric compound of p-type; and
sintering the compounds.

63. A method to obtain an energy generating system according to claim 57, wherein the thermoelectric materials are in powder form or paste form obtained by mixing powders and a binder.

64. A method to obtain an energy generating system according to claim 57, wherein the layer in photoactive material comprises a layer in semiconductor material of n-type and a layer in semiconductor material of p-type.

65. Use of the thermoelectric converter of the elementary energy generating device according to claim 34, to cool the photovoltaic converter of the elementary device.

66. Use of the thermoelectric converters of the system generating energy according to claim 43, to cool the photovoltaic converters of the system.
